(19) United States
(12) Patent Application Publication
(10) Pub. No.: US 2026/0213742 A1
(43) Pub. Date: Jul. 23, 2026

(54) PROTECTION SYSTEM, DC POWER SYSTEM, AND PROTECTION METHOD

(71) Applicant: MITSUBISHI HEAVY INDUSTRIES, LTD., Tokyo (JP)

(72) Inventors: Kazuki WATANABE, Tokyo (JP); Kyoichi SAKO, Tokyo (JP)

(73) Assignee: MITSUBISHI HEAVY INDUSTRIES, LTD., Tokyo (JP)

(21) Appl. No.: 19/138,013

(22) PCT Filed: Sep. 4, 2023
(86) PCT No.: PCT/JP2023/032282

§ 371 Date: Jun. 11, 2025

(30) Foreign Application Priority Data
Mar. 13, 2023 (JP) 2023-038666

(51) Int. Cl. H03K 17/08; H02H 1/00

(52) U.S. Cl. CPC H03K 17/08; H02H 1/0007

(57) ABSTRACT

In a protection system configured to protect a semiconductor circuit breaker that cuts off a fault current flowing from a DC electric power system to equipment connected to the system, in an event of a system failure of the DC electric power system, the semiconductor circuit breaker includes a semiconductor switch element and a clamp circuit that absorbs overvoltage generated in the semiconductor switch element. The protection system includes a monitoring device that monitors an open/close state of a switch that switches connection to a power grid of the DC electric power system; and a circuit control unit that sets a circuit constant of the clamp circuit based on a monitoring result of the monitoring device.

### FIELD

The present disclosure relates to a protection system, a DC power system, and a protection method.

### BACKGROUND

Conventionally, a semiconductor device that includes a protection circuit for protecting a semiconductor switching element from overvoltage has been known (for example, see Patent Literature 1). In this semiconductor device, the gate resistance is adjusted to reduce current flowing to the output terminal of the semiconductor switching element, such that the surge voltage at the time of turning off the semiconductor switching element is reduced.

### CITATION LIST

### Patent Literature

Patent Literature 1: Japanese Patent Application Laid-open No. 2013-126278

### SUMMARY

### Technical Problem

Incidentally, a semiconductor circuit breaker including a semiconductor switching element may be installed in a DC electric power system. In the DC electric power system, the system configuration changes depending on the open/close state of a switch for switching the connection to the DC electric power system. However, in the DC electric power system, the type of overcurrent in the event of a system failure differs depending on the system configuration. Hence, it may be difficult to suitably protect the semiconductor circuit breaker.

Thus, an object of the present disclosure is to provide a protection system, a DC power system, and a protection method capable of suitably protecting a semiconductor circuit breaker against a system failure, even when the system configuration changes in a DC electric power system.

### Solution to Problem

A protection system according to the present disclosure is configured to protect a semiconductor circuit breaker that cuts off a fault current flowing from a DC electric power system to equipment connected to the system, in an event of a system failure of the DC electric power system, wherein the semiconductor circuit breaker includes a semiconductor switch element and a clamp circuit that absorbs overvoltage generated in the semiconductor switch element. The protection system includes: a monitoring device that monitors an open/close state of a switch that switches connection to a power grid of the DC electric power system; and a circuit control unit that sets a circuit constant of the clamp circuit based on a monitoring result of the monitoring device.

A DC power system according to the present disclosure includes: a DC electric power system that includes a power grid and a switch that switches connection to the power grid; and the above-described protection system provided in the DC electric power system.

A protection method according to the present disclosure is for protecting a semiconductor circuit breaker that cuts off current flowing from a DC electric power system to equipment connected to the system, in an event of a system failure of the DC electric power system, wherein the semiconductor circuit breaker includes a semiconductor switch element and a clamp circuit that absorbs overvoltage generated in the semiconductor switch element. The protection method includes the steps of:
monitoring an open/close state of a switch that switches connection to a power grid of the DC electric power system; and setting a circuit constant of the clamp circuit based on a monitoring result.

### Advantageous Effects of Invention

According to the present disclosure, it is possible to suitably protect a semiconductor circuit breaker against a system failure, even when the system configuration changes in the power grid of the DC electric power system.

### BRIEF DESCRIPTION OF DRAWINGS

FIG. 1 is a schematic configuration diagram of a DC power system according to the present embodiment.

FIG. 2 is a schematic configuration diagram of a protection system according to the present embodiment.

FIG. 3 is an explanatory diagram illustrating the open/close state of a switch, and a relation between the gate resistance value and the drain side impedance value.

FIG. 4 is a flowchart of a protection method according to the present embodiment.

### DESCRIPTION OF EMBODIMENTS

Hereinafter, an embodiment according to the present disclosure will be described in detail with reference to the accompanying drawings. It should be noted that the disclosure is not limited to the embodiment. Moreover, components in the following embodiment include components that can be easily replaced by those skilled in the art, or components substantially the same as those components. Furthermore, the components described below can be combined as appropriate. Still furthermore, when there are a plurality of embodiments, the embodiments may be combined with one another.

### PRESENT EMBODIMENT

A protection system 20 according to the present embodiment is provided in a DC power system 10, and is a system configured to protect a semiconductor circuit breaker 16 that cuts off current flowing from a DC electric power system 12 to equipment connected to the system, in an event of a system failure of the DC electric power system.

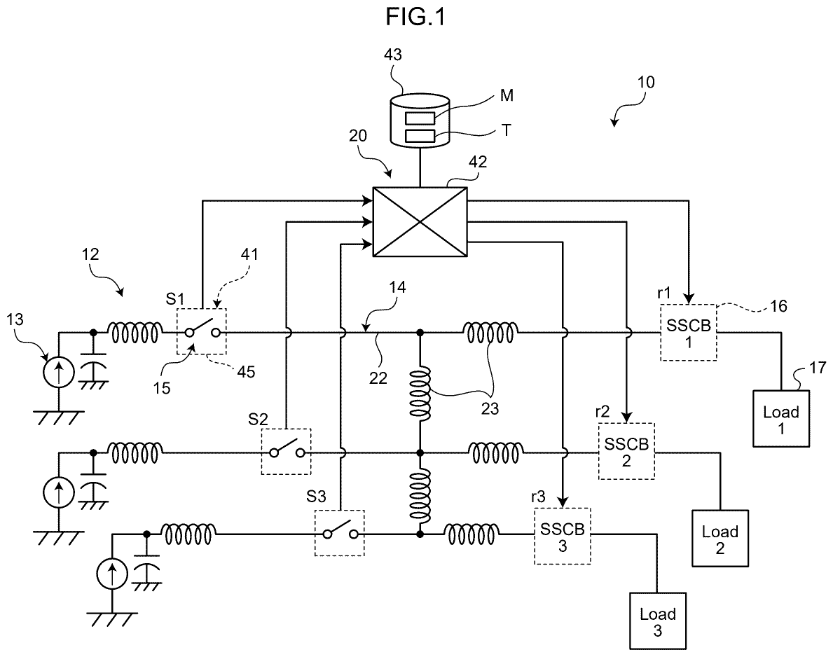

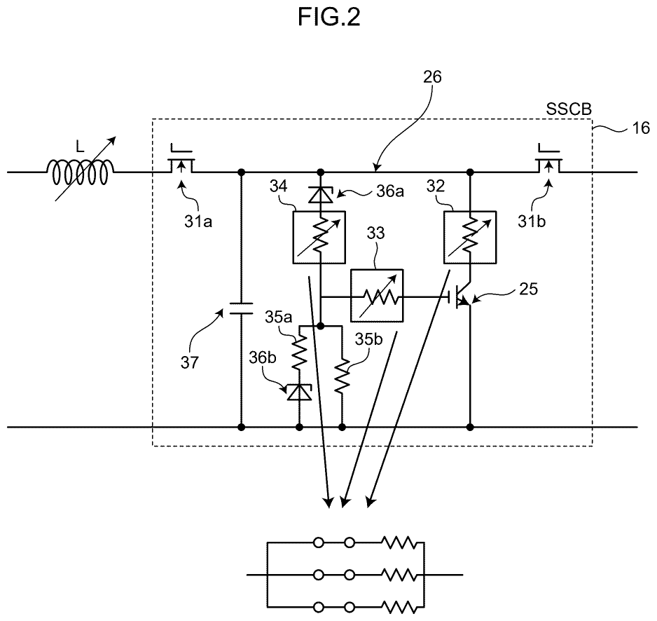

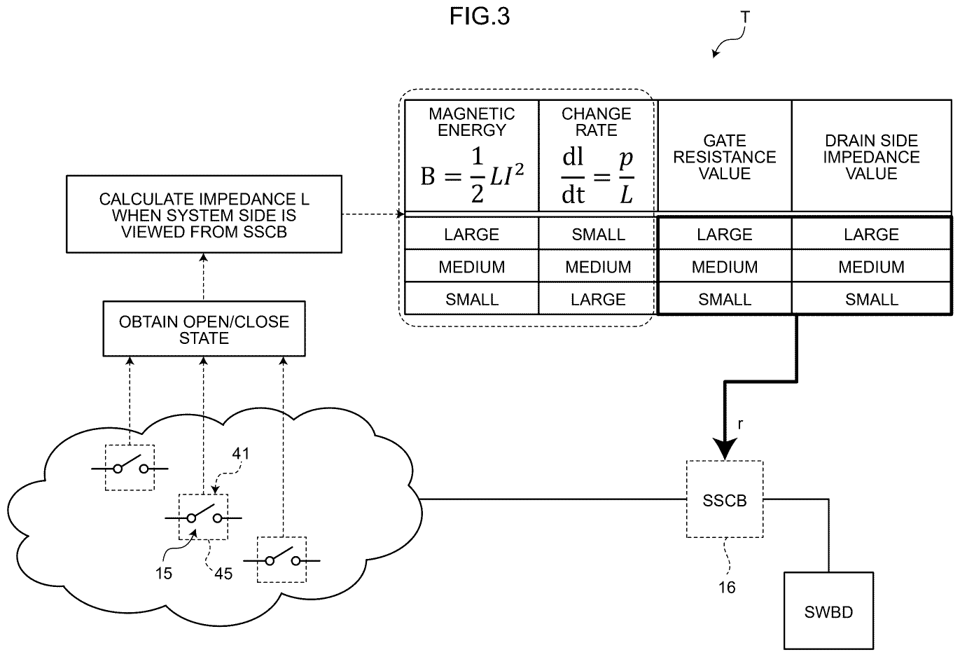

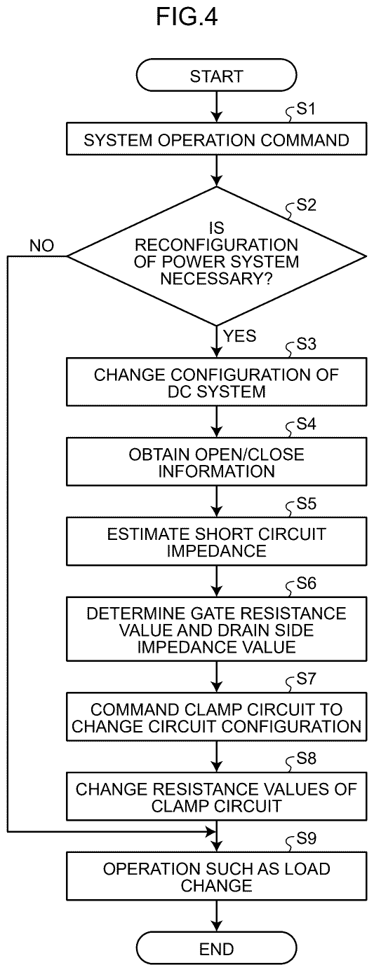

FIG. 1 is a schematic configuration diagram of a DC power system according to the present embodiment. FIG. 2 is a schematic configuration diagram of a protection system according to the present embodiment. FIG. 3 is an explanatory diagram illustrating the open/close state of a switch, and a relation between the gate resistance value and the drain side impedance value. FIG. 4 is a flowchart of a protection method according to the present embodiment. First, with reference to FIG. 1, the DC power system 10 will be described.

### (DC Power System)

The DC power system 10 is a system that supplies power by a DC method. For example, the DC power system 10 is a facility such as a DC grid installed on a mobile body, and a DC microgrid installed on land. It should be noted that a microgrid is an electric power system that can be operated independently even when the microgrid is separated from an external electric power system. As illustrated in FIG. 1, the DC power system 10 includes the DC electric power system 12 and the protection system 20.

The system configuration of the DC electric power system 12 is switchable, and a power source 13 and a load 17 are connected to the DC electric power system 12. The DC electric power system 12 includes a power grid 14, a switch 15, and a semiconductor circuit breaker 16.

For example, the power source 13 is a DC power source including an AC generator and an AC/DC converter, a battery including a storage battery, or the like. In the following description, the power source 13 is a short circuit current source that generates a short circuit current in the event of a system failure.

The power grid 14 includes a bus bar 22 and an inductor 23. The bus bar 22 is an electric path that transmits power supplied from the power source 13 to a power transmission destination. The voltage of the bus bar 22 is controlled to be constant. The inductor 23 suppresses the DC current flowing from the power source 13 side to the load 17 side that is the power transmission destination, from flowing back to the power source 13 side. A plurality of the inductors 23 are provided in the bus bar 22.

The semiconductor circuit breaker 16 is an integrated unit that includes a semiconductor switch element 25 and a clamp circuit 26. For example, the semiconductor circuit breaker 16 is a solid-state circuit breaker (SSCB). For example, the semiconductor switch element 25 is an insulated gate bipolar transistor (IGBT) or the like, and controls current flowing from the collector to the emitter, by adjusting the gate voltage. Surge voltage is generated when the semiconductor switch element 25 is turned off. However, the clamp circuit 26 reduces the surge voltage.

The clamp circuit 26 is a circuit that consumes and absorbs the energy of the fault current, and reduces the surge voltage. The clamp circuit 26 includes two overcurrent protectors 31a and 31b, a collector side variable resistor (collector side impedance) 32, a gate variable resistor 33, a current limiting variable resistor 34, two gate fixed resistors 35a and 35b, two constant voltage diodes (Zener diodes) 36a and 36b, and a capacitor 37.

For example, the two overcurrent protectors 31a and 31b are metal-oxide-semiconductor field-effect transistors (MOSFETs), and are connected to the collector side of the semiconductor switch element 25. The two overcurrent protectors 31a and 31b include the overcurrent protector 31a that suppresses the overcurrent (short circuit current) supplied from the bus bar 22 side to the semiconductor circuit breaker 16 via the inductor 23, and the overcurrent protector 31b that suppresses the overcurrent supplied to the load 17 side. The two overcurrent protectors 31a and 31b include a drain terminal, a source terminal, and a gate terminal. When the DC current supplied from the drain side to the source side becomes an overcurrent, the two overcurrent protectors 31a and 31b suppress the current by reducing the gate voltage and being turned off. Therefore, the two overcurrent protectors 31a and 31b reduce the collect current supplied to the collector side of the semiconductor switch element 25.

The collector side variable resistor 32 is connected to the collector side of the semiconductor switch element 25, and serves as a resistor that reduces the voltage of the collector current supplied via the overcurrent protectors 31a and 31b. The collector side variable resistor 32 can change the resistance value, and the resistance value is switched by a circuit control unit 42 of the protection system 20, which will be described below.

The gate variable resistor 33 is connected to the gate side of the semiconductor switch element 25, and serves as a resistor that reduces the gate voltage. The gate variable resistor 33 can change the resistance value, and the resistance value is switched by the circuit control unit 42 of the protection system 20, which will be described below.

The current limiting variable resistor 34 serves a resistor that limits the current rushing to the gate of the semiconductor switch element 25. The current limiting variable resistor 34 is provided in the electric path between the overcurrent protector 31a and the gate variable resistor 33, and is provided in series to the gate variable resistor 33. The current limiting variable resistor 34 can change the resistance value, and the resistance value is switched by the circuit control unit 42 of the protection system 20, which will be described below.

In this example, as illustrated in FIG. 2, the collector side variable resistor 32, the gate variable resistor 33, and the current limiting variable resistor 34 are mechanisms that change the resistance value by tap switching, and can switch the resistance value in a no-voltage state, for example.

The two gate fixed resistors 35a and 35b are provided in parallel between the emitter and gate of the semiconductor switch element 25. The two gate fixed resistors 35a and 35b suppress the current from the emitter side to the gate side of the semiconductor switch element 25, and reduce the gate voltage.

The two constant voltage diodes 36a and 36b include the constant voltage diode 36a provided between the gate and the collector of the semiconductor switch element 25, and the constant voltage diode 36a provided between the emitter and the gate of the semiconductor switch element 25. The constant voltage diode 36a is arranged to have a reverse voltage, with respect to the current from the overcurrent protector 31a to the gate side of the semiconductor switch element 25. The constant voltage diode 36b is arranged to have a forward voltage, with respect to the current from the emitter to the gate side of the semiconductor switch element 25. Moreover, the gate fixed resistor 35a is connected in series to the end part on the gate side of the constant voltage diode 36b.

The capacitor 37 charges when the overcurrent protectors 31a and 31b are turned on, and discharges when the overcurrent protectors 31a and 31b are turned off. The capacitor 37 is connected between the output side of the overcurrent protector 31a and the ground side of the semiconductor circuit breaker 16. The capacitor 37 supplies power to the semiconductor circuit breaker 16, by discharging when the overcurrent protectors 31a and 31b are turned off. In other words, the capacitor 37 delays the turn off of the semiconductor switch element 25, after the overcurrent protectors 31a and 31b are turned off.

In such a semiconductor circuit breaker 16, when the supplied DC current is overvoltage, the circuit control unit 42, which will be described below, turns off the overcurrent protectors 31a and 31b, by lowering the gate voltage of the overcurrent protectors 31a and 31b. Moreover, in the semiconductor circuit breaker 16, when the supplied DC current is overvoltage, a gate voltage is applied to the semiconductor switch element 25 from the constant voltage diode 36a through the current limiting variable resistor 34 and the gate variable resistor 33. It should be noted that in the semiconductor switch element 25, even when the overcurrent protector 31a is turned off, a gate voltage is applied to the gate side of the semiconductor switch element 25 from the capacitor 37, through the constant voltage diode 36a and the current limiting variable resistor 34.

When a gate voltage is applied and is turned on, the semiconductor switch element 25 causes current to flow from the collector side toward the emitter side. A part of the current that flows to the emitter side flows to the gate side of the semiconductor switch element 25, through the constant voltage diode 36b, the two gate fixed resistors 35a and 35b, and the gate variable resistor 33.

Because the gate current is reduced by the gate variable resistor 33 and the current limiting variable resistor 34, the semiconductor switch element 25 can reduce the surge voltage. Moreover, by using the collector side variable resistor 32, the semiconductor switch element 25 can reduce the voltage between the collector and the emitter to be the withstand voltage or less.

After the gate voltage is applied and is turned on, the semiconductor switch element 25 is turned off when the energy due to the fault current is consumed at each of the resistors 32, 33, 34, 35a, and 35b, and reducing the gate voltage. In this process, the energy due to the fault current is consumed at each of the resistors 32, 33, 34, 35a, and 35b. Hence, the voltage between the collector and the emitter of the semiconductor switch element 25 becomes the withstand voltage or less, and the semiconductor switch element 25 is turned off in this state.

For example, the load 17 connected to the bus bar 22 side via the semiconductor circuit breaker 16 is electrical equipment. It should be noted that a distribution board may be provided between the semiconductor circuit breaker 16 and the load 17. In other words, the semiconductor circuit breaker 16 may be provided on the upstream side of the load 17, or on the upstream side of the distribution board.

### (Protection System)

Next, the protection system 20 will be described. The protection system 20 is a system configured to protect the semiconductor circuit breaker 16 in the event of a system failure. The protection system 20 includes a monitoring device 41, the circuit control unit 42, and a storage unit 43.

The monitoring device 41 is a device that monitors the open/close state of a plurality of the switches 15 provided in the power grid 14 of the DC electric power system 12. The monitoring device 41 includes a plurality of open/close detection sensors 45 provided in each of the switches 15. The open/close detection sensors 45 are connected to the circuit control unit 42, and output switch signal S₁ to S₃ according to the open/close state of the switches 15, to the circuit control unit 42.

For example, the circuit control unit 42 includes an integrated circuit such as a central processing unit (CPU). The circuit control unit 42 controls the semiconductor circuit breaker 16 on the basis of the switch signals S₁ to S₃ that are the monitoring results obtained from the monitoring device 41. Specifically, the circuit control unit 42 sets the circuit constant of the clamp circuit 26 of the semiconductor circuit breaker 16. The circuit constant is the resistance value of each of the collector side variable resistor 32, the gate variable resistor 33, and the current limiting variable resistor 34. The circuit control unit 42 switches the resistance values of the collector side variable resistor 32, the gate variable resistor 33, and the current limiting variable resistor 34 by a tap switching mechanism such that the resistance value is based on the set circuit constant. It should be noted that the resistance values are switched when the collector side variable resistor 32, the gate variable resistor 33, and the current limiting variable resistor 34 are not operated, that is, in a no-voltage state when there is no system failure.

The storage unit 43 is any storage device such as a semiconductor storage device and a magnetic storage device. The storage unit 43 stores a calculation model M for calculating the current characteristics of the fault current, and a table (circuit constant setting information) T in which the current characteristics of the fault current and the circuit constant are associated with one another.

In this example, with reference to FIG. 3, the calculation model M and the table T will be described. The calculation model M is a model that calculates the current characteristics of the fault current generated in the DC electric power system 12 on the basis of the switch signals S₁ to S₃, and calculates at least one of the current change rate of the fault current or the magnetic energy generated by the fault current, as the current characteristics. It should be noted that the calculation model M is a calculation model that calculates on the basis of general electrical transient phenomena.

Specifically, the circuit control unit 42 calculates impedance L of the DC electric power system 12, when the power source 13 side is viewed from the semiconductor circuit breaker 16 on the basis of the switch signals S₁ to S₃, using the calculation model M. Then, the circuit control unit 42 calculates the current change rate of the fault current or the magnetic energy generated by the fault current, from the calculated impedance L.

In the table T, current characteristics of the fault current and the circuit constant are associated with one another. As illustrated in FIG. 3, in the table T, the current change rate of the fault current, the magnetic energy generated by the fault current, the gate resistance value, and the collector side resistance value are associated with one another. Specifically, in the table T, the gate resistance value and the collector side resistance value are associated with one another such that the gate resistance value and the collector side resistance value are reduced with a reduction in the magnetic energy (E=Lᵢ ²/2) generated by the fault current. Moreover, in the table T, the gate resistance value and the collector side resistance value are associated with one another such that the gate resistance value and the collector side resistance value are reduced with an increase in the current change rate (di/dt=v/L) of the fault current.

It should be noted that in the present embodiment, the circuit constant is set using the calculation model M and the table T. However, any configuration may be used as long as the circuit constant can be set on the basis of the open/close state of the switch 15. For example, a table in which the open/close state of the switch 15 is directly associated with the circuit constant may be used.

### (Protection Method)

Next, with reference to FIG. 4, a protection method using the protection system 20 will be described. The protection method illustrated in FIG. 4 is executed in a state where a fault current is not generated in the DC electric power system 12, and the semiconductor circuit breaker 16 is protected on the basis of the circuit constant set by the protection method, when a fault current is generated.

First, the DC power system 10 obtains a command related to the system operation (step S1). Then, the DC power system 10 determines whether the reconfiguration of the DC power system 10 is necessary, on the basis of the obtained system operation (step S2). If it is determined that the reconfiguration of the DC power system 10 is necessary (Yes at step S2), the DC power system 10 performs open/close control of the switch 15 provided in the DC electric power system 12, and configures a system according to the system operation (step S3). Subsequently, the protection system 20 obtains the switch signals S1 to S3 according to the open/close state of the switch 15 as open/close information (step S4). The circuit control unit 42 of the protection system 20 calculates the impedance L estimated at the time of short circuit from the calculation model M, on the basis of the obtained switch signals S₁ to S₃ (step S5). Subsequently, the circuit control unit 42 calculates the current characteristics of the fault current from the calculated impedance L, and determines and obtains the gate resistance value and the collector side resistance value serving as the circuit constants corresponding to the current characteristics from the table T, on the basis of the calculated current characteristics (step S6). The circuit control unit 42 outputs a command for changing the circuit configuration toward the clamp circuit 26 such that the circuit constants are the obtained gate resistance value and the collector side resistance value (step S7). On the basis of the obtained circuit constants, the clamp circuit 26 changes the gate resistance value and the collector side resistance value (step S8). Then, the DC power system 10 executes an operation such as a load change by the reconfigured system (step S9). On the other hand, if it is determined that the reconfiguration of the DC power system 10 is not necessary at step S2 (No at step S2), the process proceeds to step S9, and the DC power system 10 executes an operation such as a load change. After executing step S9, the protection system 20 completes a series of processes related to the protection method.

It should be noted that in the present embodiment, the monitoring device 41 monitors the open/close state of the switches 15. However, it does not particularly limit the configuration of the monitoring device 41. In addition to monitoring the open/close state of the switches 15, the monitoring device 41 may also monitor the current characteristics of the fault current generated in the DC electric power system 12. For example, the current characteristics of the fault current include a current value, a voltage value, frequency, and the like. In this case, the circuit control unit 42 may correct the impedance L calculated using the calculation model M, using the current characteristics of the fault current. Consequently, the circuit control unit 42 can improve the calculation accuracy of the impedance L, and set appropriate circuit constants.

As described above, for example, the protection system 20, the DC power system 10, and the protection method described in the present embodiment can be understood as follows.

The protection system 20 according to a first aspect is the protection system 20 configured to protect the semiconductor circuit breaker 16 that cuts off a fault current flowing from the DC electric power system 12 to a power transmission destination, in the event of a system failure of the DC electric power system 12. In the protection system 20, the semiconductor circuit breaker 16 includes the semiconductor switch element 25 and the clamp circuit 26 that absorbs overvoltage generated in the semiconductor switch element 25. The protection system 20 includes the monitoring device 41 that monitors the open/close state of the switch 15 for switching the connection to the power grid 14 of the DC electric power system 12, and the circuit control unit 42 that sets a circuit constant of the clamp circuit 26 on the basis of the monitoring result of the monitoring device 41.

With this configuration, it is possible to set the circuit constant of the clamp circuit 26 to correspond to the system configuration of the DC electric power system 12 according to the open/close state of the switch 15. Therefore, even when the system configuration of the DC electric power system 12 changes, it is possible to suitably protect the semiconductor circuit breaker 16 against a system failure.

As a second aspect, the protection system 20 according to the first aspect further includes the storage unit 43 that stores the calculation model M for calculating the current characteristics of the fault current generated in the DC electric power system 12 on the basis of the open/close state of the switch 15, and the circuit constant setting information (table T) in which the current characteristics of the fault current generated in the DC electric power system 12 and the circuit constant are associated with one another. The circuit control unit 42 estimates the current characteristics of the fault current using the calculation model M, from the open/close state of the switch 15 on the basis of the monitoring results; obtains the circuit constant associated with the estimated current characteristics of the fault current, by referring the circuit constant setting information; and sets the obtained circuit constant to the clamp circuit 26.

With this configuration, by estimating the current characteristics of the fault current according to the system configuration of the DC electric power system 12, it is possible to appropriately set the circuit constant of the clamp circuit 26. Hence, it is possible to more suitably protect the semiconductor circuit breaker 16.

As a third aspect, in the circuit constant setting information of the protection system 20 according to the second aspect, the current characteristics of the fault current and the circuit constant are associated with one another such that at least one of the gate resistance value and the collector side resistance value of the semiconductor switch element 25 serving as the circuit constant is reduced with an increase in the current change rate of the fault current, or with a reduction in the magnetic energy generated by the fault current.

With this configuration, it is possible to set appropriate circuit constants according to the current characteristics of the fault current.

As a fourth aspect, in the protection system 20 according to any one of the first to third aspects, the monitoring device 41 further monitors the current characteristics of the fault current generated in the DC electric power system 12, and the circuit control unit 42 sets the circuit constant on the basis of the open/close state of the switch and the current characteristics of the fault current.

With this configuration, because the current characteristics of the fault current according to the system configuration of the DC electric power system 12 can be estimated more accurately, it is possible to appropriately set the circuit constant of the clamp circuit 26. Hence, it is possible to more suitably protect the semiconductor circuit breaker 16.

As a fifth aspect, in the protection system 20 according to any one of the first to fourth aspects, the semiconductor circuit breaker 16 is provided on the upstream side of the load 17 connected to the power grid 14.

With this configuration, it is possible to suppress the effects of the fault current on the load 17, while suitably protecting the semiconductor circuit breaker 16.

As a sixth aspect, in the protection system 20 according to any one of the first to fourth aspects, the semiconductor circuit breaker is provided on the upstream side of a distribution board connected to the power grid.

With this configuration, it is possible to suppress the effects of the fault current on the distribution board, while suitably protecting the semiconductor circuit breaker 16.

The DC power system 10 according to a seventh aspect includes the DC electric power system 12 that includes the power grid 14 and the switch 15 for switching the connection to the power grid 14; and the protection system 20 described above provided in the DC electric power system 12.

With this configuration, even when the system configuration of the DC electric power system 12 changes, it is possible to suppress the effects of the fault current on the load 17 and the like, while suitably protecting the semiconductor circuit breaker 16 against a system failure.

A protection method according to an eighth aspect is the protection method for protecting the semiconductor circuit breaker 16 that cuts off current flowing from the DC electric power system 12 to a power transmission destination, in the event of a system failure of the DC electric power system 12. In the protection method, the semiconductor circuit breaker 16 includes the semiconductor switch element 25 and the clamp circuit 26 that absorbs overvoltage generated in the semiconductor switch element 25. The protection method executes the step S4 of monitoring the open/close state of the switch 15 for switching the connection to the power grid 14 of the DC electric power system 12, and the step S8 of setting a circuit constant of the clamp circuit 26 on the basis of the monitoring results.

With this configuration, it is possible to set the circuit constant of the clamp circuit 26 to correspond to the system configuration of the DC electric power system 12 according to the open/close state of the switch 15. Therefore, even when the system configuration of the DC electric power system 12 changes, it is possible to suitably protect the semiconductor circuit breaker 16 against a system failure.

### REFERENCE SIGNS LIST

10 DC power system
12 DC electric power system
13 Power source
14 Power grid
15 Switch
16 Semiconductor circuit breaker
17 Load
20 Protection system
22 Bus bar
23 Inductor
25 Semiconductor switch element
26 Clamp circuit
31a, 31b Overcurrent protector
32 Collector side variable resistor
33 Gate variable resistor
34 Current limiting variable resistor
35a, 35b Gate fixed resistor
36a, 36b Constant voltage diode
37 Capacitor
41 Monitoring device
42 Circuit control unit
43 Storage unit
45 Open/close detection sensor
T Table
M Calculation model

1. A protection system configured to protect a semiconductor circuit breaker that cuts off a fault current flowing from a DC electric power system to equipment connected to the system, in an event of a system failure of the DC electric power system, wherein the semiconductor circuit breaker includes a semiconductor switch element and a clamp circuit that absorbs overvoltage generated in the semiconductor switch element, the protection system comprising:
a monitoring device that monitors an open/close state of a switch that switches connection to a power grid of the DC electric power system; and
a circuit control unit that sets a circuit constant of the clamp circuit based on a monitoring result of the monitoring device.

2. The protection system according to claim 1, further comprising a storage unit that stores a calculation model for calculating a current characteristic of the fault current generated in the DC electric power system based on the open/close state of the switch, and circuit constant setting information in which the current characteristic of the fault current generated in the DC electric power system and the circuit constant are associated with one another, wherein
the circuit control unit estimates the current characteristic of the fault current using the calculation model, from the open/close state of the switch based on the monitoring result; obtains the circuit constant associated with the estimated current characteristic of the fault current, by referring the circuit constant setting information; and sets the obtained circuit constant to the clamp circuit.

3. The protection system according to claim 2, wherein in the circuit constant setting information, the current characteristic of the fault current is associated with the circuit constant such that at least one of a gate resistance value and a collector side resistance value of the semiconductor switch element serving as the circuit constant is reduced with an increase in a current change rate of the fault current, or with a reduction in magnetic energy generated by the fault current.

4. The protection system according to claim 1, wherein
the monitoring device further monitors a current characteristic of the fault current generated in the DC electric power system, and
the circuit control unit sets the circuit constant based on the open/close state of the switch and the current characteristic of the fault current.

5. The protection system according to claim 1, wherein the semiconductor circuit breaker is provided on an upstream side of a load connected to the power grid.

6. The protection system according to claim 1, wherein the semiconductor circuit breaker is provided on an upstream side of a distribution board connected to the power grid.

7. A DC power system, comprising:
a DC electric power system that includes a power grid and a switch that switches connection to the power grid; and
the protection system according to claim 1 provided in the DC electric power system.

8. A protection method for protecting a semiconductor circuit breaker that cuts off current flowing from a DC electric power system to equipment connected to the system, in an event of a system failure of the DC electric power system, wherein the semiconductor circuit breaker includes a semiconductor switch element and a clamp circuit that absorbs overvoltage generated in the semiconductor switch element, the protection method comprising:
monitoring an open/close state of a switch that switches connection to a power grid of the DC electric power system; and
setting a circuit constant of the clamp circuit based on a monitoring result.
